(19) United States
(12) Patent Application Publication
(10) Pub. No.: US 2008/0265370 A1
(43) Pub. Date: Oct. 30, 2008

(54) Semiconductor device

(75) Inventor: Satoshi Kageyama, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/081,967

(22) Filed: Apr. 24, 2008

(30) Foreign Application Priority Data
Apr. 27, 2007 (JP) 2007-119387

(51) Int. Cl. H01L 29/92

(52) U.S. Cl. 257/532; 257/E29.343

(57) ABSTRACT

In the semiconductor device according to the present invention, a lower electrode and an upper electrode are relatively positionally deviated from each other through a capacitance film in a direction perpendicular to the laminating direction thereof. Thus, the upper electrode and the lower electrode each have portions opposed to each other through the capacitance film in the laminating direction and portions not opposed to each other. An upper electrode plug is connected to the portion of the upper electrode not opposed to the lower electrode through an upper electrode contact hole passing through an insulating film formed on the upper electrode. Further, a lower electrode plug is connected to the portion of the lower electrode not opposed to the upper electrode through a lower electrode contact hole passing through the insulating film.

### BACKGROUND OF THE INVENTION

1. Field of the Invention

The present invention relates to a semiconductor device having a capacitance element of an MIM (Metal-Insulator-Metal) structure.

2. Description of Related Art

A capacitance element having a structure (MIM structure) holding an insulating capacitance film between a lower electrode and an upper electrode exhibits a small resistive component and allows an increase in capacitance density, whereby the same is drawing an attention as a capacitance element mounted on an LSI, particularly for a radio communication system.

The lower electrode and the upper electrode of the capacitance element having the MIM structure are generally formed from a metal film containing Al (aluminum). However, there has been a study on application of Cu (copper) having a higher conductivity instead of Al to the material for the lower electrode in order to further reduce the resistance.

FIGS. 3A to 3H are schematic sectional views successively showing the steps of manufacturing a semiconductor device using Cu for a lower electrode.

First, a semiconductor substrate having an interlayer dielectric film 51 on the outermost surface is prepared. Then, a lower electrode 52 made of Cu is formed on the surface layer portion of the interlayer dielectric film 51 by a damascene process. Thereafter a capacitance film 53 made of SiN (silicon nitride) and a metal film 54 made of TiN (titanium nitride) are formed on the interlayer dielectric film 51 in this order, as shown in FIG. 3A.

Then, a resist pattern is formed on the metal film 54 and employed as a mask for etching the metal film 54, thereby forming an upper electrode 55, as shown in FIG. 3B. After termination of the etching, the resist pattern remaining on the upper electrode 55 (metal film 54) is removed.

Thereafter another interlayer dielectric film 56 is laminated on the capacitance film 53 and the upper electrode 55 to cover the same, as shown in FIG. 3C. Then, a resist pattern is formed on the interlayer dielectric film 56 and employed as a mask for etching the interlayer dielectric film 56. Thus, trough-holes 57 and 58 partially exposing the capacitance film 53 and the upper film 55 respectively are formed in the interlayer dielectric film 56.

The etching through the resist pattern serving as the mask is further continued for forming an opening 59 in the capacitance film 53 for contact with the lower electrode 52, as shown in FIG. 3D. At this time, not only the capacitance film 53, but also the portion of the upper electrode 55 exposed through the through-hole 58 is etched.

Then, a resist pattern 60 is formed on the interlayer dielectric film 56, as shown in FIG. 3E. This resist pattern 60 has an opening 66 exposing the through-hole 57 and the peripheral region of the through-hole 57 in the interlayer dielectric film 56 and an opening 67 exposing the through-hole 58 and the peripheral region of the through-hole 58 in the interlayer dielectric film 56.

Thereafter the resist pattern 60 is employed as a mask for etching the interlayer dielectric film 56, thereby forming trenches 61 and 62 for embedding wires in the interlayer dielectric film 56, as shown in FIG. 3F. After termination of the etching, the resist pattern 60 remaining on the resist pattern 60 is removed.

Then, copper 63 is deposited on the interlayer dielectric film 56, the portion of the lower electrode 52 exposed from the through-hole 57 and the portion of the upper electrode 55 exposed from the through-hole 58 by electrolytic plating, as shown in FIG. 3G. The copper 63 fills up the trenches 61 and 62, the through-holes 57 and 58 and the opening 59 to cover the overall surface of the interlayer dielectric film 56.

Thereafter the copper 63 overflowing the trenches 61 and 62 is removed by CMP, so that the surface of the copper 63 is flush with the interlayer dielectric film 56 with each other. Thus, a lower electrode contact plug 64 is formed to be connected to the lower electrode 52 through the trench 61, the through-hole 57 and the opening 59 and an upper electrode contact plug 65 is formed to be connected to the upper electrode 55 through the trench 62 and the through-hole 58, and the semiconductor device is obtained in the structure shown in FIG. 3H.

In the steps of forming the through-holes 57 and 58 and the opening 59, however, the opening 59 may not be formed or the upper electrode 55 may be perforated due to excessive etching depending on the time (etching time) for etching the capacitance film 53 and the interlayer dielectric film 56, due to the small diameters of the through-holes 57 and 58 and the difference between the distances from the surface of the interlayer dielectric film 56 to the surfaces (upper surfaces) of the lower electrode 52 and the upper electrode 55.

If the etching time is set long, for example, the upper electrode 55 may be excessively etched. Therefore, a through-hole may be formed in the upper electrode 55 and may be further formed to the capacitance film 53. If the through-hole is formed in the capacitance film 53, a path causing a capacitor leak is formed between the lower electrode 52 and the upper electrode 55 (upper electrode contact plug 65). If the etching time is set short, on the other hand, it may not be possible to form the opening 59 in the capacitance film 53, and the lower electrode 52 and the lower electrode contact plug 64 may not be conducted.

### SUMMARY OF THE INVENTION

An object of the present invention is to provide a semiconductor device capable of reliable conduction of a lower electrode and a lower electrode plug while capable of reliable prevention for formation of a path causing a capacitor leak between the lower electrode and an upper electrode.

A semiconductor device according to one aspect of the present invention includes: a flat lower electrode; a capacitance film laminated on the lower electrode; a flat upper electrode laminated on the capacitance film and positionally deviated from the lower electrode in a direction orthogonal to the laminating direction to be partially opposed to a part of the lower electrode through the capacitance film; an upper insulating film laminated on the upper electrode; an upper electrode plug connected to a portion of the upper electrode not opposed to the lower electrode through an upper electrode contact hole passing through the upper insulating film in the laminating direction; and a lower electrode plug connected to a portion of the lower electrode not opposed to the upper electrode through a lower electrode contact hole passing through the upper insulating film in the laminating direction.

In this semiconductor device, the lower electrode and the upper electrode are relatively positionally deviated from each other through the capacitance film in the direction orthogonal to the laminating direction thereof. Thus, the upper electrode and the lower electrode each have portions opposed to each other through the capacitance film in the laminating direction and the portions not opposed to each other. The upper electrode plug is connected to the portion of the upper electrode not opposed to the lower electrode through the upper electrode contact hole passing through the insulating film formed on the upper electrode. Further, the lower electrode plug is connected to the portion of the lower electrode not opposed to the upper electrode through the lower electrode contact hole passing through the insulating film.

The upper electrode contact hole and the lower electrode contact hole can be formed through the same step by forming a resist pattern having openings opposed to portions where the upper electrode contact hole and the lower electrode contact hole on the insulating film should be formed and etching the insulating film (and the capacitance film) through this resist pattern serving as a mask.

The upper electrode contact hole is formed on the position not opposed to the lower electrode in the laminating direction, and the lower electrode contact hole is formed on the position not opposed to the upper electrode in the laminating direction. When the etching time is set to a period necessary and sufficient for forming the lower electrode contact hole (for a period reliably forming the lower electrode contact hole through the insulating film), the lower electrode is not exposed through the upper electrode contact hole even if the upper electrode contact hole passes through the upper electrode. Therefore, the lower electrode and the lower electrode plug can be reliably conducted, while the lower electrode and the upper electrode can be reliably prevented from formation of a path causing a capacitor leak therebetween.

The semiconductor device may further include a lower insulating film provided on a opposite side to the side provided with the upper electrode with respect to the capacitance film and having a trench facing the capacitance film. The lower electrode may be made of a metal having copper as a main component, and may be embedded in the trench.

When the material for the lower electrode has copper as a main component as described above, the lower electrode can be formed by forming the trench in the lower insulating film and embedding this material in the trench.

The foregoing and other objects, features and effects of the present invention will become more apparent from the following detailed description of the embodiments with reference to the attached drawings.

### BRIEF DESCRIPTION OF THE DRAWINGS

FIG. 1 is a sectional view schematically showing the structure of a semiconductor device according to an embodiment of the present invention;

FIG. 2A is a schematic sectional view showing a step of manufacturing a semiconductor device;

FIG. 2B is a schematic sectional view showing a step of manufacturing the semiconductor device subsequently to FIG. 2A;

FIG. 2C is a schematic sectional view showing a step of manufacturing the semiconductor device subsequently to FIG. 2B;

FIG. 2D is a schematic sectional view showing a step of manufacturing the semiconductor device subsequently to FIG. 2C;

FIG. 2E is a schematic sectional view showing a step of manufacturing the semiconductor device subsequently to FIG. 2D;

FIG. 2F is a schematic sectional view showing a step of manufacturing the semiconductor device subsequently to FIG. 2D;

FIG. 2G is a schematic sectional view showing a step of manufacturing the semiconductor device subsequently to FIG. 2F;

FIG. 3A is a schematic sectional view showing a step of manufacturing a conventional semiconductor device;

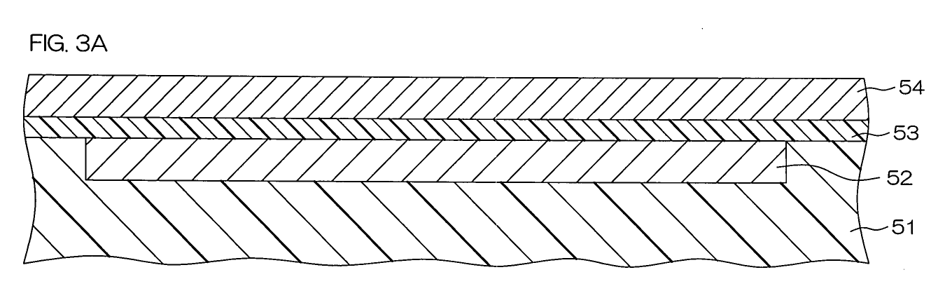

FIG. 3B is a schematic sectional view showing a step of manufacturing the semiconductor device subsequently to FIG. 3A;

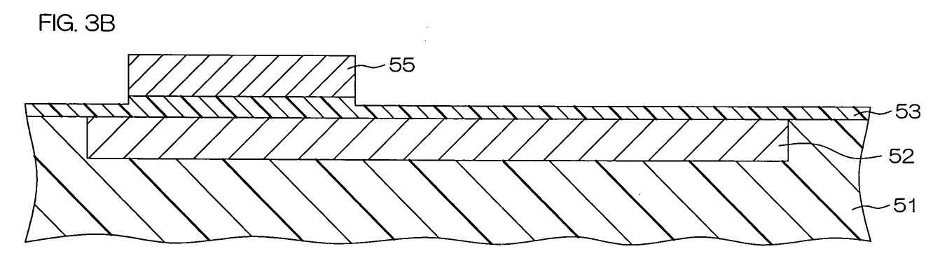

FIG. 3C is a schematic sectional view showing a step of manufacturing the semiconductor device subsequently to FIG. 3B;

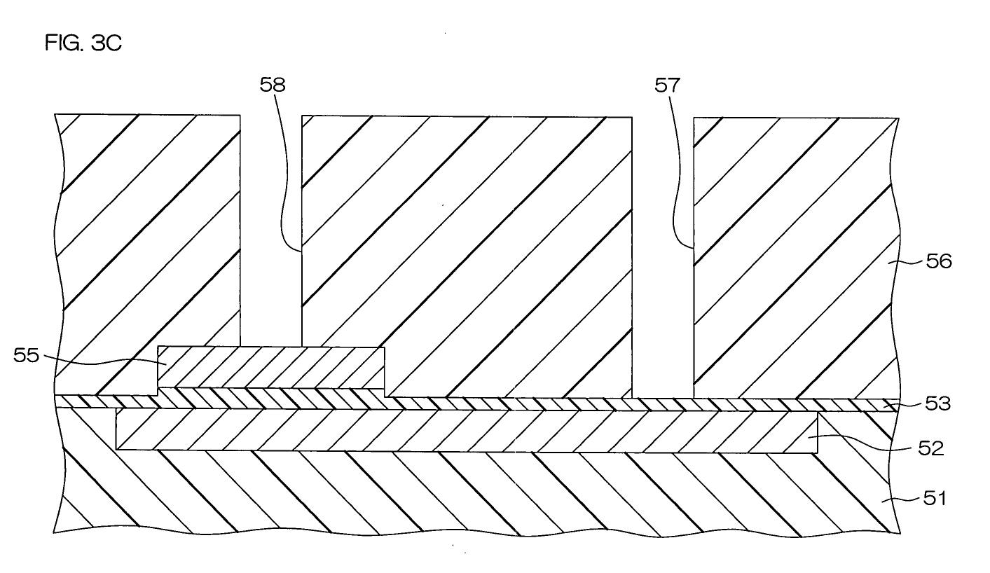

FIG. 3D is a schematic sectional view showing a step of manufacturing the semiconductor device subsequently to FIG. 3C;

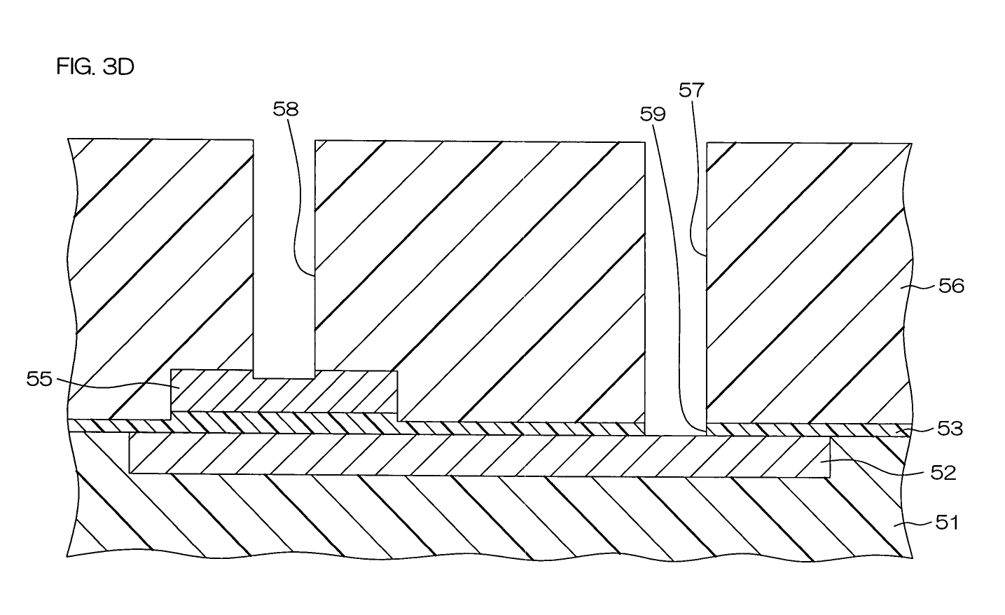

FIG. 3E is a schematic sectional view showing a step of manufacturing the semiconductor device subsequently to FIG. 3D;

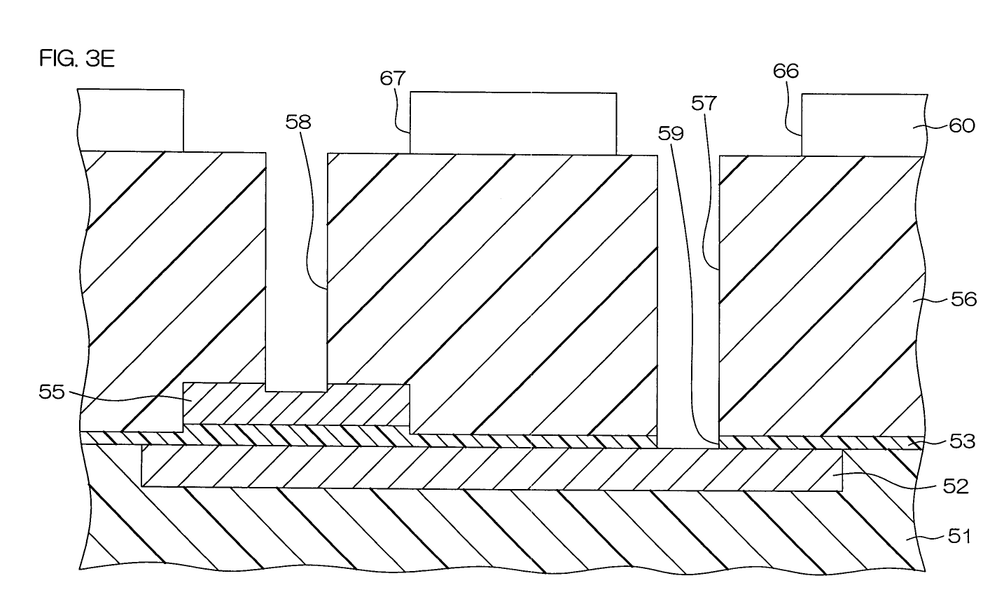

FIG. 3F is a schematic sectional view showing a step of manufacturing the semiconductor device subsequently to FIG. 3D;

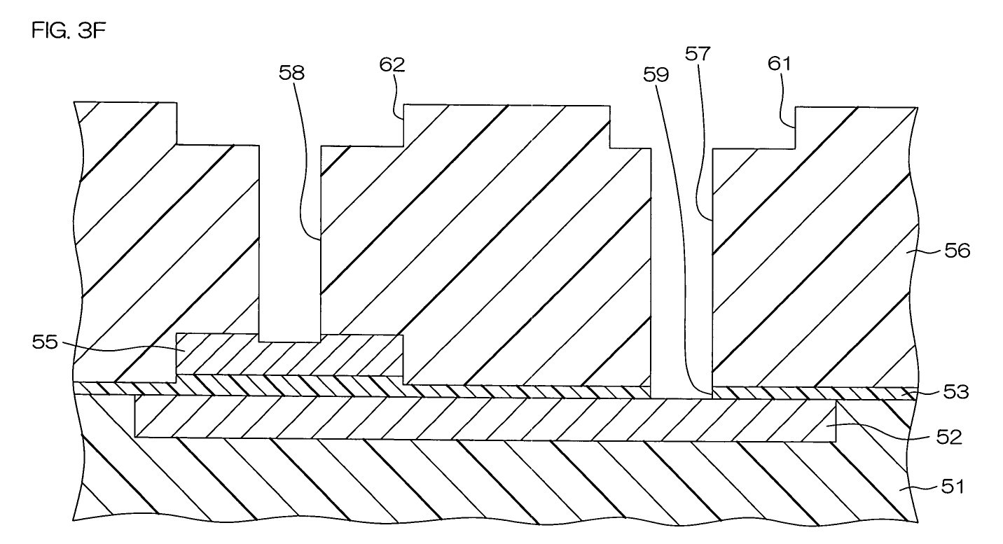

FIG. 3G is a schematic sectional view showing a step of manufacturing the semiconductor device subsequently to FIG. 3F; and

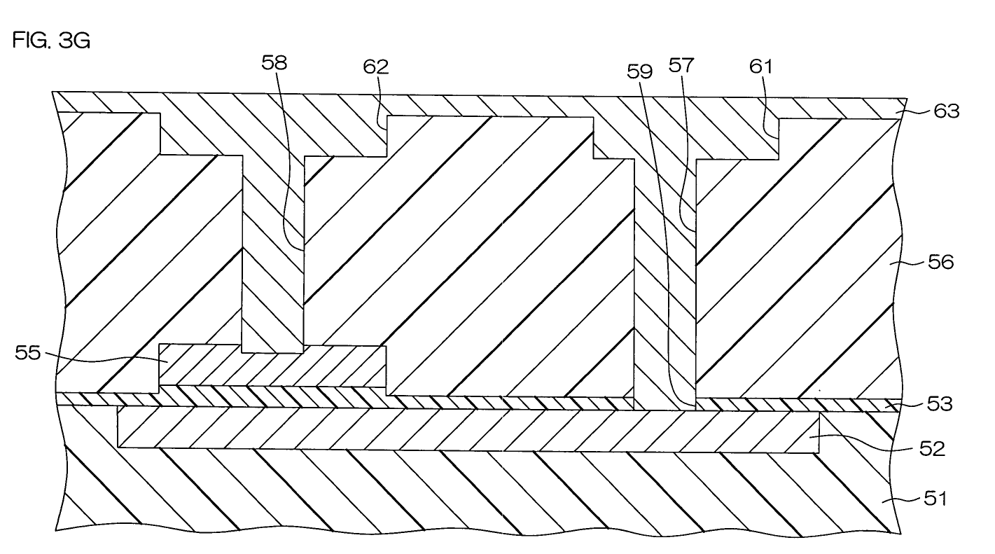

FIG. 3H is a schematic sectional view showing a step of manufacturing the semiconductor device subsequently to FIG. 3G.

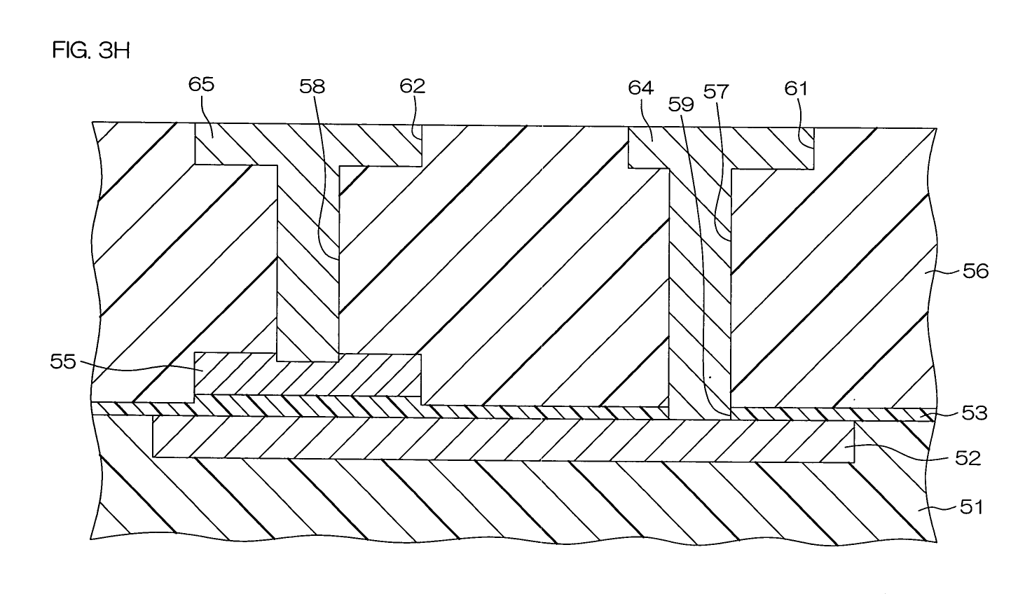

### DETAILED DESCRIPTION OF PREFERRED EMBODIMENTS

An embodiment of the present invention is now described in detail with reference to the accompanying drawings.

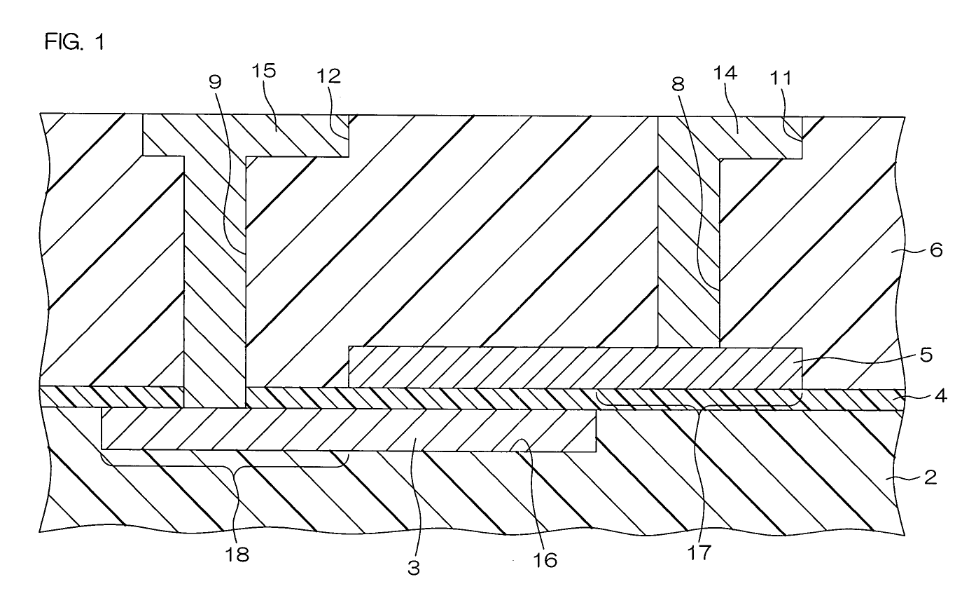

FIG. 1 is a sectional view schematically showing the structure of a semiconductor device according to the embodiment of the present invention.

This semiconductor device 1 includes an interlayer dielectric film 2 made of SiO₂ (silicon oxide) on a semiconductor substrate (not shown) built with a functional element such as a MOSFET (Metal Oxide Semiconductor Field Effect Transistor). The interlayer dielectric film 2 may be made of a Low-k film material such as SiOC (carbon-doped silicon oxide) or SiOF (fluorine-doped silicon oxide), for example.

On the surface layer portion of the interlayer dielectric film 2, a flat lower electrode 3 made of a metal having Cu as a main component is embedded in a trench 16. The surface of the lower electrode 3 is generally flush with the surface of the interlayer dielectric film 2.

A capacitance film 4 made of SiN is laminated on the interlayer dielectric film 2 and the lower electrode 3.

A flat upper electrode 5 made of TiN is formed on the capacitance film 4. This upper electrode 5 is positionally deviated from the lower electrode 3 in a direction orthogonal to the laminating direction. Thus, the upper electrode 5 is partially opposed to a part of the lower electrode 3 through the capacitance film 4, while the remaining part thereof forms a non-opposed portion 17 not opposed to the lower electrode 3. The lower electrode 3 is partially opposed to the part of the upper electrode 5 through the capacitance film 4, while the remaining part thereof forms a non-opposed portion 18 not opposed to the upper electrode 5.

An interlayer dielectric film 6 made of SiO₂ is formed on the capacitance film 4 and the upper electrode 5. This interlayer dielectric film 6 may also be made of a Low-k film material such as SiOC or SiOF, for example, similarly to the interlayer dielectric film 2.

A lower electrode contact hole 9 is formed through the capacitance film 4 and the interlayer dielectric film 6 in the laminating direction thereof for partially exposing the non-opposed portion 18 of the lower electrode 3 from the capacitance film 4 and the interlayer dielectric film 6. A lower electrode trench 12 communicating with the lower electrode contact hole 9 and having a larger opening area than the lower electrode contact hole 9 is formed on the surface layer portion of the interlayer dielectric film 6. A lower electrode contact plug 15 made of a metal such as W (tungsten) or Cu is embedded in the lower electrode contact hole 9 and the lower electrode trench 12.

An upper electrode contact hole 8 is formed through the interlayer dielectric film 6 in the laminating direction with respect to the upper electrode 5 for partially exposing the non-opposed portion 17 of the upper electrode 5 from the interlayer dielectric film 6. An upper electrode trench 11 communicating with the upper electrode contact hole 8 and having a larger opening area than the upper electrode contact hole 8 is formed on the surface layer portion of the interlayer dielectric film 6. An upper electrode contact plug 14 made of a metal such as W or Cu is embedded in the upper electrode contact hole 8 and the upper electrode trench 11.

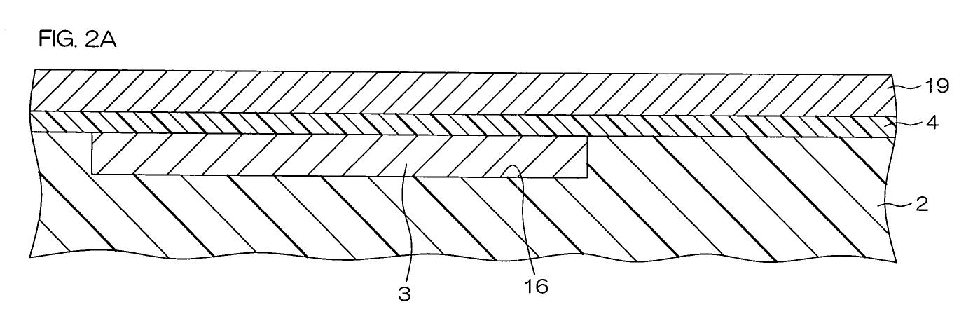

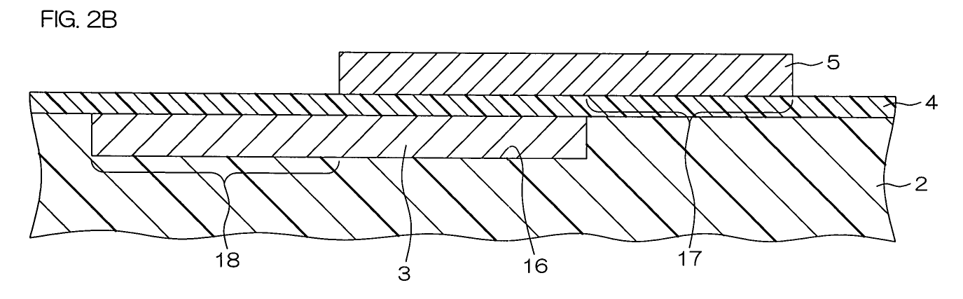

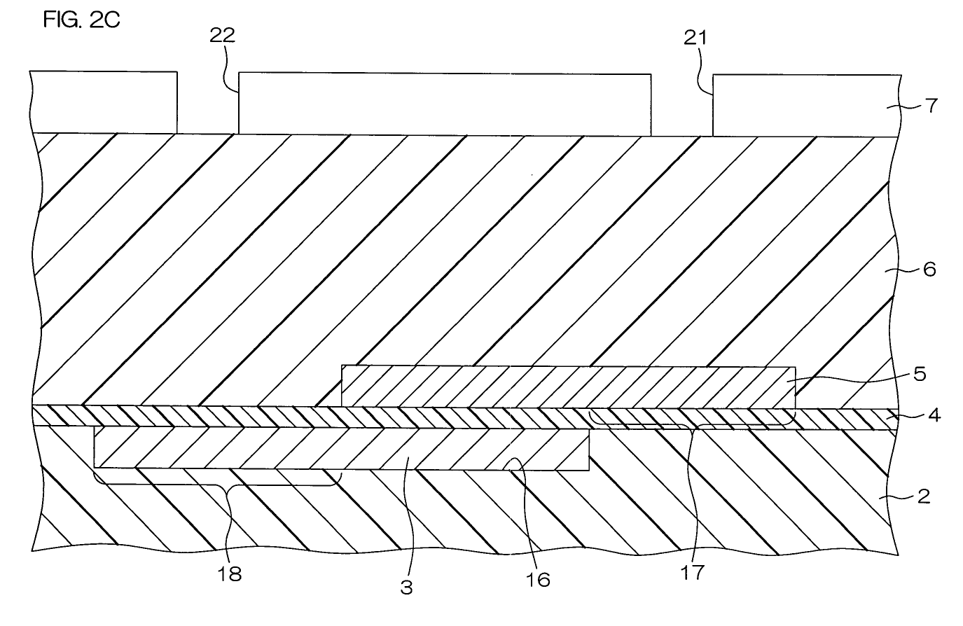

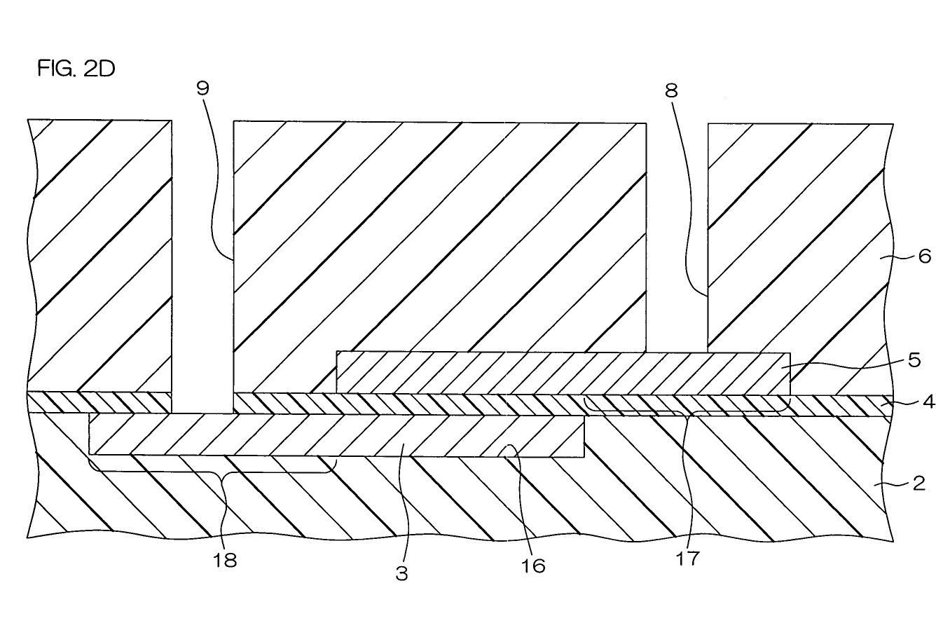

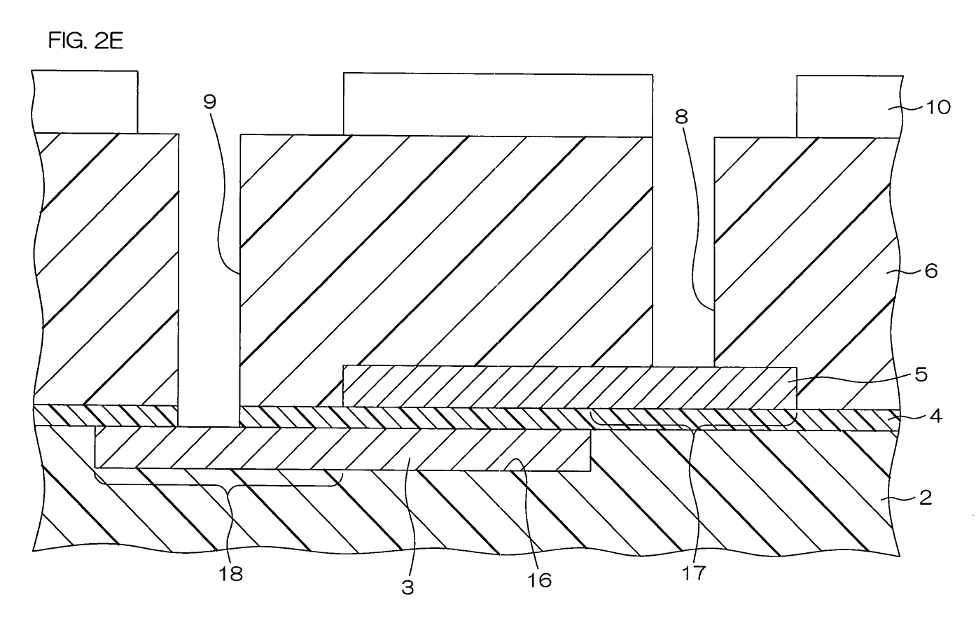

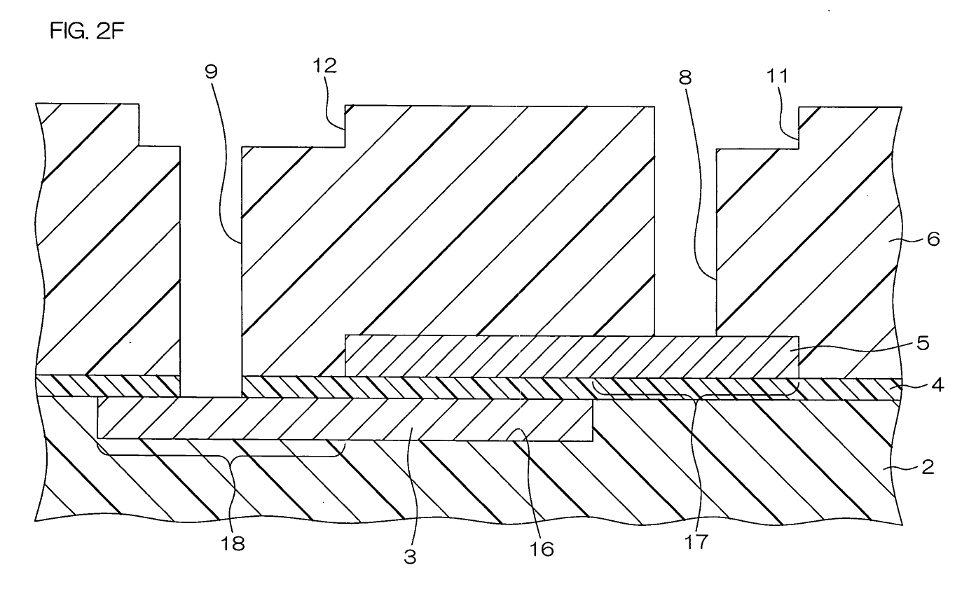

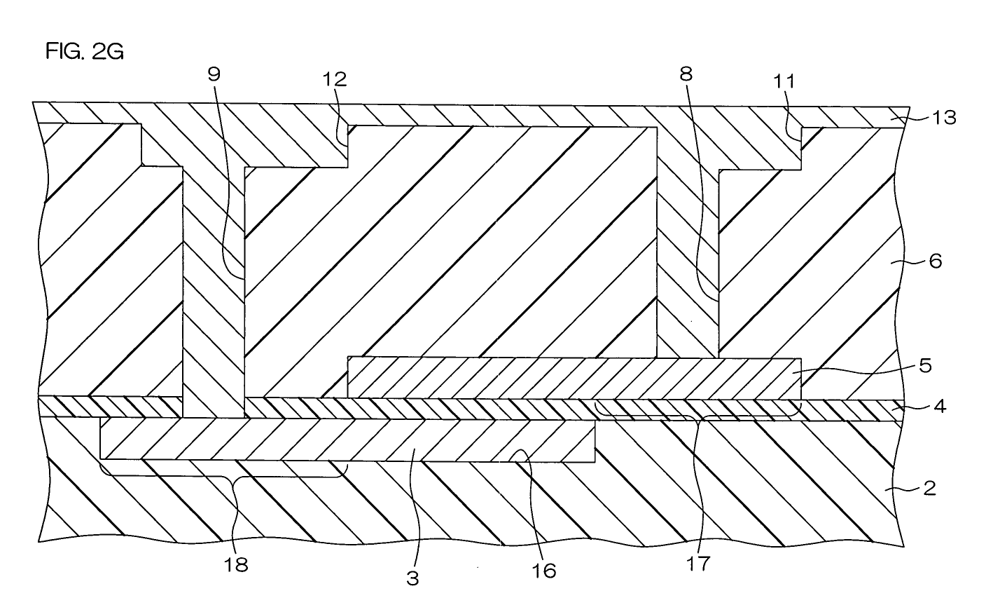

FIGS. 2A to 2G are schematic sectional views successively showing the steps of manufacturing the semiconductor device 1.

First, a semiconductor substrate having the interlayer dielectric film 2 on the outermost surface is prepared. The lower electrode 3 embedded in the surface layer portion of the interlayer dielectric film 2 is formed by a damascene process. Thereafter the capacitance film 4 and a metallic material deposition layer 19 made of the material for the upper electrode 5 are laminated on the interlayer dielectric film 2 in this order, as shown in FIG. 2A. The capacitance film 4 can be formed by plasma CVD (Chemical Vapor Deposition), for example. The metallic material deposition layer 19 can be formed by sputtering, for example.

Then, a resist pattern (not shown) having a shape corresponding to the upper electrode 5 is formed on the metallic material deposition layer 19. This resist pattern is employed as a mask for etching the metallic material deposition layer 19, thereby forming the upper electrode 5 as shown in FIG. 2B. After termination of the etching, the resist pattern remaining on the upper electrode 5 is removed.

Thereafter the interlayer dielectric film 6 is formed on the capacitance film 4 and the upper electrode 5, as shown in FIG. 2C. The interlayer dielectric film 6 can be formed by sputtering, for example. Then, a resist pattern 7 having a first opening 21 and a second opening 22 corresponding to the upper electrode contact hole 8 and the lower electrode contact hole 9 respectively is formed on the interlayer dielectric film 6.

The resist pattern 7 is employed as a mask for etching the interlayer dielectric film 6. Thus, the upper electrode contact hole 8 is formed through the interlayer dielectric film 6, as shown in FIG. 2D. Further, the etching progresses up to the capacitance film 4 in the portion exposed from the second opening 22 of the resist pattern 7 to form the lower electrode contact hole 9 continuously passing through the interlayer dielectric film 6 and the capacitance film 4. After the formation of the upper electrode contact hole 8 and the lower electrode contact hole 9, the resist pattern 7 is removed.

Thereafter a resist pattern 10 having openings corresponding to each of the upper electrode trench 11 and the lower electrode trench 12 is formed, as shown in FIG. 2E. This resist pattern 10 is employed as a mask for etching the interlayer dielectric film 6. Thus, the upper electrode trench 11 and the lower electrode trench 12 are formed in the interlayer dielectric film 6, as shown in FIG. 2F. After termination of the etching, the resist pattern 10 is removed.

Then, a material 13 for the upper electrode contact plug 14 and the lower electrode contact plug 15 is deposited by electrolytic plating to fill up the upper electrode trench 11, the lower electrode trench 12, the upper electrode contact hole 8 and the lower electrode contact hole 9 and to cover the overall surface of the interlayer dielectric film 6, as shown in FIG. 2G.

Thereafter the surface of the deposition layer of the material 13 is smoothed by CMP, along with the surface of the interlayer dielectric film 6 to form the lower electrode contact plug 15 connected to the lower electrode 3 through the lower electrode trench 12 and the lower electrode contact hole 9 and the upper electrode contact plug 14 connected to the upper electrode 5 through the upper electrode trench 11 and the upper electrode contact hole 8. Consequently, the semiconductor device 1 having the structure shown in FIG. 1 is obtained.

In the semiconductor device 1, as hereinabove described, the lower electrode 3 and the upper electrode 5 are relatively positionally deviated from each other through the capacitance film 4 in the direction orthogonal to the laminating direction thereof. Thus, the upper electrode 5 and the lower electrode 3 have the portions opposed to each other through the capacitance film 4 and the non-opposed portions 17 and 18 not opposed to each other, respectively. The upper electrode plug 14 is connected to the non-opposed portion 17 of the upper electrode 5 not opposed to the lower electrode 3 through the upper electrode contact hole 8 passing through the interlayer dielectric film 6 formed on the upper electrode 5. The lower electrode plug 15 is connected to the non-opposed portion 18 of the lower electrode 3 not opposed to the upper electrode 5 through the lower electrode contact hole 9 passing through the interlayer dielectric film 6.

The upper electrode contact hole 8 and the lower electrode contact hole 9 can be formed through the same step by forming the resist pattern 7 having the openings 21 and 22 opposing to the portions where the upper electrode contact hole 8 and the lower electrode contact hole 9 on the dielectric film 6 should be formed and etching the interlayer dielectric film 6 (and the capacitance film 4) through the resist pattern 7 serving as a mask.

The upper electrode contact hole 8 is formed on the position not opposed to the lower electrode 3 in the laminating direction, and the lower electrode contact hole 9 is formed on the position not opposed to the upper electrode 5 in the laminating direction. When the etching time is set to a period necessary and sufficient for forming the lower electrode contact hole 9 (for a period reliably forming the lower electrode contact hole 9 in the interlayer dielectric film 6), the lower electrode 3 is not exposed through the upper electrode contact hole 8 even if the upper electrode contact hole 8 passes through the upper electrode 5. Therefore, the lower electrode 3 and the lower electrode plug 14 can be reliably conducted, while the lower electrode 3 and the upper electrode 5 can be reliably prevented from formation of a path causing a capacitor leak therebetween.

While the capacitance film 4 made of SiN is illustrated in this embodiment, SiC (silicon carbide), SiOC, SiCN (silicon carbonitride), Ta₂O₅ or the like may be employed as the material for the capacitance film 4.

While the upper electrode 5 made of TiN is illustrated in this embodiment, Al, an Al alloy, Ti (titanium), a Ti compound, Ta (tantalum) or a Ta compound may be employed as the material for the upper electrode 5.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2007-119387 filed with the Japanese Patent Office on date Apr. 27, 2007, the disclosure of which is incorporated herein by reference.

What is claimed is:

1. A semiconductor device comprising:
a flat lower electrode;
a capacitance film laminated on the lower electrode;
a flat upper electrode laminated on the capacitance film and positionally deviated from the lower electrode in a direction orthogonal to the laminating direction to be partially opposed to a part of the lower electrode through the capacitance film;
an upper insulating film laminated on the upper electrode;
an upper electrode plug connected to a portion of the upper electrode not opposed to the lower electrode through an upper electrode contact hole passing through the upper insulating film in the laminating direction; and
a lower electrode plug connected to a portion of the lower electrode not opposed to the upper electrode through a lower electrode contact hole passing through the upper insulating film in the laminating direction.

2. The semiconductor device according to claim 1, further comprising a lower insulating film provided on a opposite side to the side provided with the upper electrode with respect to the capacitance film and having a trench facing the capacitance film, wherein
the lower electrode is made of a metal having copper as a main component, and embedded in the trench.
